(19) United States
(12) Patent Application Publication
(10) Pub. No.: US 2021/0367582 A1
(43) Pub. Date: Nov. 25, 2021

(54) BULK-ACOUSTIC WAVE RESONATOR AND METHOD FOR FABRICATING BULK-ACOUSTIC WAVE RESONATOR

(71) Applicant: Samsung Electro-Mechanics Co., Ltd, Suwon-si (KR)

(72) Inventors: Tae Kyung LEE, Suwon-si (KR); Ran Hee SHIN, Suwon-si (KR); Chang Hyun LIM, Suwon-si (KR); Tae Yoon KIM, Suwon-si (KR); Sang Kee YOON, Suwon-si (KR); Moon Chul LEE, Suwon-si (KR); Jae Goon AUM, Suwon-si (KR)

(73) Assignee: Samsung Electro-Mechanics Co., Ltd, Suwon-si (KR)

(21) Appl. No.: 17/104,703

(22) Filed: Nov. 25, 2020

(30) Foreign Application Priority Data
May 25, 2020 (KR) 10-2020-0062471
Aug. 24, 2020 (KR) 10-2020-0106353

(51) Int. Cl. H03H 9/17; H03H 9/02; H03H 9/13; H03H 3/02; H01L 41/29; H01L 41/35

(52) U.S. Cl. CPC H03H 9/171; H03H 9/02015; H03H 9/13; H03H 9/176; H01L 41/29; H01L 41/35; H03H 3/02

(57) ABSTRACT

A bulk-acoustic wave resonator includes: a substrate; and a resonator portion in which a first electrode, a piezoelectric layer, and a second electrode are sequentially stacked on the substrate. The piezoelectric layer is formed of aluminum nitride (AlN) containing scandium (Sc). The bulk-acoustic wave resonator satisfies the following expression: leakage current density×scandium (Sc) content<20. The leakage current density is a leakage current density of the piezoelectric layer in μA/cm2, and the scandium (Sc) content is a weight percentage (wt %) of scandium (Sc) in the piezoelectric layer.

### CROSS-REFERENCE TO RELATED APPLICATIONS

This application claims the benefit under 35 U.S.C. § 119(a) of Korean Patent Application Nos. 10-2020-0062471 and 10-2020-0106353 filed on May 25, 2020 and Aug. 24, 2020, respectively, in the Korean Intellectual Property Office, the entire disclosures of which are incorporated herein by reference for all purposes.

### BACKGROUND

### 1. Field

The following description relates to a bulk-acoustic wave resonator and a method for manufacturing a bulk-acoustic wave resonator.

### 2. Description of Related Art

In accordance with the trend for the miniaturization of wireless communication devices, the miniaturization of high frequency component technology has been demanded. For example, a bulk-acoustic wave (BAW) type filter using semiconductor thin film wafer manufacturing technology may be implemented in wireless communication devices.

A bulk-acoustic resonator (BAW) is formed, for example, when a thin film-type element, which is configured to cause resonance using piezoelectric characteristics of a piezoelectric dielectric material deposited on a semiconductor substrate (e.g., a silicon wafer), is implemented as a filter.

Recently, technological interest in 5G communications has been increasing, and the development of technologies that can be implemented in candidate bands of 5G communications is being performed.

However, in the case of 5G communications using a Sub 6 GHz (4 to 6 GHz) frequency band, since the bandwidth is increased and the communication distance is shortened, the strength or power of the signal of the bulk-acoustic wave resonator may be increased. In addition, as the frequency increases, losses occurring in the piezoelectric layer or the resonator may increase.

Therefore, a bulk-acoustic wave resonator capable of maintaining stable characteristics even under high voltage/high power conditions is desired.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a bulk-acoustic wave resonator includes: a substrate; and a resonator portion in which a first electrode, a piezoelectric layer, and a second electrode are sequentially stacked on the substrate. The piezoelectric layer is formed of aluminum nitride (AlN) containing scandium (Sc). The bulk-acoustic wave resonator satisfies the following expression: leakage current density×scandium (Sc) content<20, wherein the leakage current density is a leakage current density of the piezoelectric layer in μA/cm2, and the scandium (Sc) content is a weight percentage (wt %) of scandium (Sc) in the piezoelectric layer.

The scandium content may be 10 wt % to 40 wt %.

The leakage current density may be 2 μA/cm2 or less.

A ratio of a breakdown voltage of the piezoelectric layer, in volts, to a thickness of the piezoelectric layer, in Å, may be 0.025 or more.

The bulk-acoustic wave resonator may further include an insertion layer partially disposed in the resonator portion and disposed below the piezoelectric layer. The piezoelectric layer and the second electrode may be at least partially raised by the insertion layer.

The resonator portion may include a central portion disposed in a central region of the resonator portion and an extension portion disposed at a periphery of the central portion. The insertion layer may be disposed only in the extension portion of the resonator portion. The insertion layer may have an inclined surface having a thickness increasing in a direction away from the central portion. The piezoelectric layer may include an inclined portion disposed on the inclined surface.

In a cross-section cut to across the resonator portion, an end of the second electrode may be disposed at a boundary between the central portion and the extension portion, or disposed on the inclined portion.

The piezoelectric layer may further include a piezoelectric portion disposed in the central portion and an extension portion extending outwardly of the inclined portion. At least a portion of the second electrode may be disposed on the extension portion of the piezoelectric layer.

In another general aspect, a method for manufacturing a bulk-acoustic wave resonator includes: forming a resonator portion in which a first electrode, a piezoelectric layer, and a second electrode are sequentially stacked on a substrate. The forming of the resonator portion comprises forming the piezoelectric layer by forming an aluminum scandium nitride (AlScN) thin film, and then performing a rapid thermal annealing (RTA) process on the AlScN thin film. The bulk-acoustic wave resonator satisfies the following expression: leakage current density×scandium (Sc) content<20, wherein the leakage current density is a leakage current density of the piezoelectric layer in μA/cm2, and the scandium (Sc) content is a weight percentage (wt %) of scandium (Sc) in the piezoelectric layer.

The scandium (Sc) content may be 10 wt % to 40 wt %.

The forming of the AlScN thin film may be performed through a sputtering process using aluminum-scandium (AlSc) as a target.

The leakage current density may be 2 μA/cm2 or less.

A ratio of a breakdown voltage of the piezoelectric layer, in volts, to a thickness of the piezoelectric layer, in Å, may be 0.025 or more.

The method may further include forming an insertion layer below the piezoelectric layer. The piezoelectric layer and the second electrode may be at least partially raised by the insertion layer.

The insertion layer may have an inclined surface. In a cross-section cut to across the resonator portion, at least a portion of an end of the second electrode may be disposed to overlap the insertion layer.

The resonator portion may include a central portion disposed in a central region of the resonator portion, and an extension portion disposed along a periphery of the central portion. The end of the second electrode may be disposed in the extension portion.

In another general aspect, a bulk-acoustic wave resonator includes: a substrate; and a resonator portion in which a first electrode, a piezoelectric layer, and a second electrode are sequentially stacked on the substrate. The piezoelectric layer is formed of aluminum nitride (AlN) containing scandium (Sc) in an amount of 10 wt % to 40 wt %. A leakage current density of the piezoelectric layer is 2 μA/cm2 or less, as measured in an electric field of 0.1V/nm between the first electrode and the second electrode.

A ratio of a breakdown voltage of the piezoelectric layer, in volts, to a thickness of the piezoelectric layer, in Å, is 0.025 or more.

The piezoelectric layer may contain scandium in an amount of 10 wt % to 30 wt %.

The bulk-acoustic wave resonator may further include an insertion layer disposed below the piezoelectric layer in the resonator portion. Portions of the piezoelectric layer and the second electrode may be inclined by the insertion layer.

In another general aspect, a method for manufacturing a bulk-acoustic wave resonator includes: forming a resonator portion in which a first electrode, a piezoelectric layer, and a second electrode are sequentially stacked on a substrate. The forming of the piezoelectric layer includes forming an aluminum scandium nitride (AlScN) thin film containing scandium (Sc) in an amount of 10 wt % to 40 wt %, and then performing a rapid thermal annealing (RTA) process on the AlScN thin film at a temperature of 500° C. or higher.

The AlScN thin film may contain scandium in an amount of 10 wt % to 30 wt %.

The performing of the rapid thermal annealing (RTA) process on the AlScN thin film at a temperature of 500° C. or higher may include performing the rapid thermal annealing (RTA) process on the AlScN thin film at a temperature of 600° C. to 900° C.

A leakage current density of the piezoelectric layer may be 2 μA/cm2 or less, as measured in an electric field of 0.1V/nm between the first electrode and the second electrode.

Other features and aspects will be apparent from the following detailed description, the drawings, and the claims.

### BRIEF DESCRIPTION OF DRAWINGS

FIG. 1 is a plan view of a bulk-acoustic wave resonator, according to an embodiment.

FIG. 2 is a cross-sectional view taken along line I-I′of FIG. 1.

FIG. 3 is a cross-sectional view taken along line II-II′ of FIG. 1.

FIG. 4 is a cross-sectional view taken along line III-III′ in FIG. 1.

FIG. 5 is a view illustrating a measurement of leakage current density according to a scandium (Sc) content of a piezoelectric layer.

FIG. 6 is a graph created based on the leakage current characteristic of FIG. 5.

FIG. 7 is a graph illustrating a leakage current according to an RTA process temperature.

FIG. 8 is a graph illustrating characteristics of a filter using the bulk-acoustic wave resonator of FIG. 1.

FIG. 9 is a cross-sectional view schematically illustrating a bulk-acoustic wave resonator, according to an embodiment.

FIG. 10 is a cross-sectional view schematically illustrating a bulk-acoustic wave resonator, according to an embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Herein, it is noted that use of the term “may” with respect to an embodiment or example, e.g., as to what an embodiment or example may include or implement, means that at least one embodiment or example exists in which such a feature is included or implemented while all examples and examples are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after gaining an understanding of the disclosure of this application. Further, although the examples described herein have a variety of configurations, other configurations are possible as will be apparent after an understanding of the disclosure of this application.

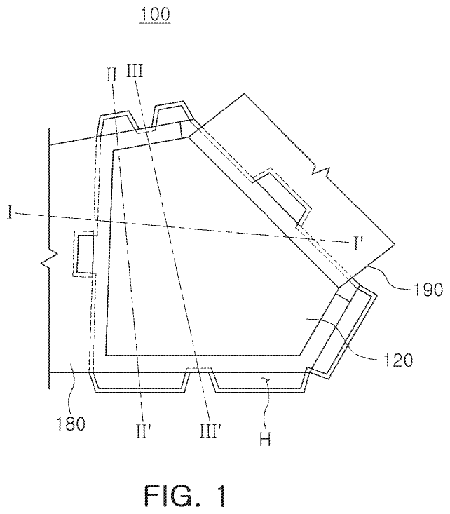

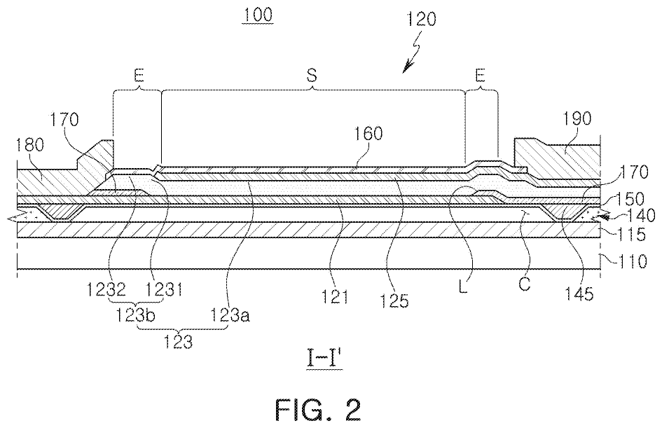

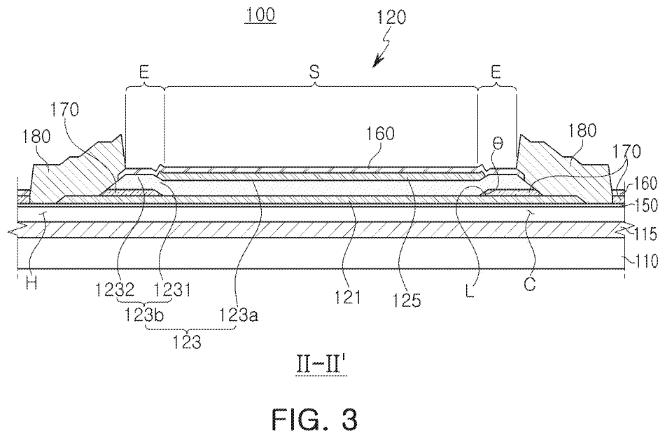

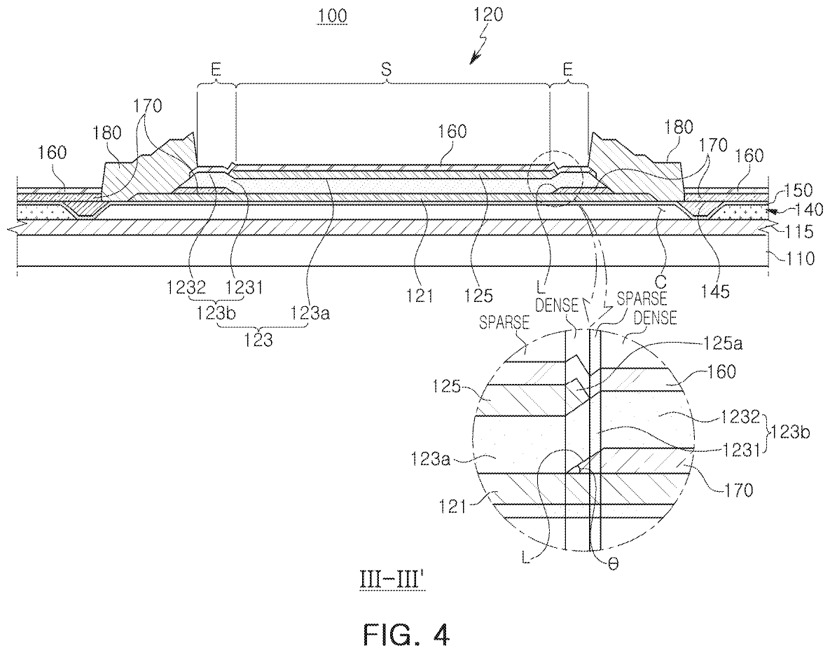

FIG. 1 is a plan view of an acoustic wave resonator 100, according to an embodiment. FIG. 2 is a cross-sectional view taken along line I-I′ of FIG. 1. FIG. 3 is a cross-sectional view taken along line II-II′ of FIG. 1. FIG. 4 is a cross-sectional view taken along line III-III′ of FIG. 1.

Referring to FIGS. 1 to 4, the acoustic wave resonator 100 may be a bulk-acoustic wave (BAW) resonator, and may include, for example, a substrate 110, a sacrificial layer 140, a resonator portion 120, and an insertion layer 170.

The substrate 110 may be a silicon substrate. For example, a silicon wafer or a silicon on insulator (SOI) type substrate may be used as the substrate 110.

An insulating layer 115 may be provided on an upper surface of the substrate 110 to electrically isolate the substrate 110 and the resonator portion 120. In addition, the insulating layer 115 may prevent the substrate 110 from being etched by an etching gas when a cavity C is formed in a manufacturing process of the acoustic-wave resonator 100. In this case, the insulating layer 115 may be formed of any one or any combination of any two or more of silicon dioxide (SiO₂), silicon nitride (Si₃N₄), aluminum oxide (Al₂O₃), and aluminum nitride (AlN), and may be formed through any one process among chemical vapor deposition, RF magnetron sputtering, and evaporation.

A sacrificial layer 140 is formed on the insulating layer 115, and the cavity C and an etch stop portion 145 are disposed in the sacrificial layer 140.

The cavity C is formed as an empty space, and may be formed by removing a portion of the sacrificial layer 140.

As the cavity C is formed in the sacrificial layer 140, the resonator portion 120, which is formed above the sacrificial layer 140, may be formed to be entirely flat.

The etch stop portion 145 is disposed along a boundary of the cavity C. The etch stop portion 145 is provided to prevent etching from being performed beyond a cavity region in a process of forming the cavity C.

A membrane layer 150 is formed on the sacrificial layer 140, and forms an upper surface of the cavity C. Therefore, the membrane layer 150 is also formed of a material that is not easily removed in the process of forming the cavity C.

For example, when a halide-based etching gas such as fluorine (F), chlorine (Cl), or the like is used to remove a portion (e.g., a cavity region) of the sacrificial layer 140, the membrane layer 150 may be made of a material having low reactivity with the etching gas. In this case, the membrane layer 150 may include either one or both of silicon dioxide (SiO₂) and silicon nitride (Si₃N₄).

In addition, the membrane layer 150 may be made of a dielectric layer containing any one or any combination of any two or more of magnesium oxide (MgO), zirconium oxide (ZrO₂), aluminum nitride (AlN), lead zirconate titanate (PZT), gallium arsenide (GaAs), hafnium oxide (HfO₂), and aluminum oxide (Al₂O₃), titanium oxide (TiO₂), and zinc oxide (ZnO), or a metal layer containing any one or any combination of any two or more of aluminum (Al), nickel (Ni), chromium (Cr), platinum (Pt), gallium (Ga), and hafnium (Hf). However, the membrane layer 150 is not limited to the foregoing examples.

The resonator portion 120 includes a first electrode 121, a piezoelectric layer 123, and a second electrode 125. The resonator portion 120 is configured such that the first electrode 121, the piezoelectric layer 123, and the second electrode 125 are stacked in order from a bottom of the resonator portion 120. Therefore, the piezoelectric layer 123 is disposed between the first electrode 121 and the second electrode 125 in the resonator portion 120.

Since the resonator portion 120 is formed on the membrane layer 150, the membrane layer 150, the first electrode 121, the piezoelectric layer 123, and the second electrode 125 are sequentially stacked on the substrate 110, to form the resonator portion 120.

The resonator portion 120 may resonate the piezoelectric layer 123 according to signals applied to the first electrode 121 and the second electrode 125 to generate a resonant frequency and an anti-resonant frequency.

The resonator portion 120 may include a central portion S in which the first electrode 121, the piezoelectric layer 123, and the second electrode 125 are stacked to be substantially flat, and an extension portion E in which an insertion layer 170 is interposed between the first electrode 121 and the piezoelectric layer 123.

The central portion S is a region disposed in a center of the resonator portion 120, and the extension portion E is a region disposed along a periphery of the central portion S. Therefore, the extension portion E is a region extended externally from the central portion S, and is a region formed to have a continuous annular shape along the periphery of the central portion S. However, in another example, the extension portion E may be configured to have a discontinuous annular shape, in which some regions are disconnected from other regions.

Accordingly, as shown in FIG. 2, in the cross-section of the resonator portion 120 cut so as to cross the central portion S, the extension portion E is disposed on both ends of the central portion S, respectively. The insertion layer 170 is disposed on both sides of the extension portion E disposed on both ends of the central portion S.

The insertion layer 170 has an inclined surface L having a thickness increases as a distance from the central portion S increases.

In the extension portion E, the piezoelectric layer 123 and the second electrode 125 are disposed on the insertion layer 170. Therefore, portions of the piezoelectric layer 123 and the second electrode 125 located in the extension portion E have an inclined surface along the shape of the insertion layer 170.

In the embodiment of FIG. 2, the extension portion E is included in the resonator portion 120, and accordingly, resonance may also occur in the extension portion E. However, the disclosure is not limited to such a configuration, and resonance may not occur in the extension portion E depending on the structure of the extension portion E. That is, resonance may occur only in the central portion S.

The first electrode 121 and the second electrode 125 may be formed of a conductor, for example, gold, molybdenum, ruthenium, iridium, aluminum, platinum, titanium, tungsten, palladium, tantalum, chromium, nickel, or a metal containing any one of gold, molybdenum, ruthenium, iridium, aluminum, platinum, titanium, tungsten, palladium, tantalum, chromium, and nickel, but is not limited to the foregoing materials.

In the resonator portion 120, the first electrode 121 is formed to have a larger area than the second electrode 125, and a first metal layer 180 is disposed along a periphery of the first electrode 121 on the first electrode 121. Therefore, the first metal layer 180 may be disposed to be spaced apart from the second electrode 125 by a predetermined distance, and may be disposed in a form surrounding the resonator portion 120.

Since the first electrode 121 is disposed on the membrane layer 150, the first electrode 121 is formed to be entirely flat. On the other hand, since the second electrode 125 is disposed on the piezoelectric layer 123, curving of the second electrode 125 may be formed corresponding to the shape of the piezoelectric layer 123.

The first electrode 121 may be used as either one of an input electrode and an output electrode configured to input or output, respectively, an electrical signal such as a radio frequency (RF) signal.

The second electrode 125 may be disposed throughout an entirety of the central portion S, and may be disposed in a portion of the extension portion E. Accordingly, the second electrode 125 may include a portion disposed on a piezoelectric portion 123a of the piezoelectric layer 123 to be described in more detail later, and a portion disposed on a curved portion 123b of the piezoelectric layer 123.

More specifically, the second electrode 125 may be disposed to cover an entirety of the piezoelectric portion 123a and a portion of an inclined portion 1231 of the piezoelectric layer 123. Accordingly, a portion 125a of the second electrode (FIG. 4) disposed in the extension portion E may be formed to have an area smaller than an area of an inclined surface of the inclined portion 1231, and a portion of the second electrode 125 disposed in the resonator portion 120 may be formed to have an area than an area of the piezoelectric layer 123.

Accordingly, as shown in FIG. 2, in a cross-section of the resonator portion 120 cut so as to cross the central portion S, an end of the second electrode 125 is disposed in the extension portion E. In addition, at least a portion of the end of the second electrode 125 disposed in the extension portion E is disposed to overlap the insertion layer 170. Here, ‘overlap’ means that if the second electrode 125 was to be projected on a plane on which the insertion layer 170 is disposed, a shape of the second electrode 125 projected on the plane would overlap the insertion layer 170.

The second electrode 125 may be used as any one of an input electrode and an output electrode for inputting and outputting an electrical signal such as a radio frequency (RF) signal, or the like. That is, when the first electrode 121 is used as the input electrode, the second electrode 125 may be used as the output electrode, and when the first electrode 121 is used as the output electrode, the second electrode 125 may be used as the input electrode.

As illustrated in FIG. 4, when the end of the second electrode 125 is positioned on the inclined portion 1231 of the piezoelectric layer 123 to be described in more detail later, since a local structure of an acoustic impedance of the resonator portion 120 is formed in a sparse/dense/sparse/dense structure from the central portion S, a reflective interface configured to reflect a lateral wave inwardly of the resonator portion 120 is increased. Therefore, since most lateral waves cannot flow outwardly of the resonator portion 120, and are reflected and then flow to an interior of the resonator portion 120, the performance of the acoustic resonator 100 may be improved.

The piezoelectric layer 123 is a portion configured to convert electrical energy into mechanical energy in a form of elastic waves through a piezoelectric effect, and is formed on the first electrode 121 and the insertion layer 170 to be described in more detail later.

Zinc oxide (ZnO), aluminum nitride (AlN), doped aluminum nitride, lead zirconate titanate, quartz, and the like may be selectively used as a material of the piezoelectric layer 123. In an example in which the piezoelectric layer is formed of doped aluminum nitride, a rare earth metal, a transition metal, or an alkaline earth metal may be further included. The rare earth metal may include any one or any combination of any two or more of scandium (Sc), erbium (Er), yttrium (Y), and lanthanum (La). The transition metal may include any one or any combination of any two or more of hafnium (Hf), titanium (Ti), zirconium (Zr), tantalum (Ta), and niobium (Nb). In addition, the alkaline earth metal may include magnesium (Mg).

When a content of elements doped with aluminum nitride (AlN) is less than 0.1 at %, a piezoelectric property higher than that of aluminum nitride (AlN) cannot be realized. When the content of the elements exceeds 30 at %, it is difficult to fabricate and control the composition for deposition, such that uneven crystalline phases may be formed. Therefore, in the embodiment of FIGS. 1-4, the content of elements doped with aluminum nitride (AlN) may be in a range of 0.1 to 30 at %.

Additionally, in the embodiment of FIGS. 1-4, the piezoelectric layer 123 may be doped with scandium (Sc) in aluminum nitride (AlN). In this case, a piezoelectric constant may be increased to increase Kₜ² of the acoustic resonator.

As described above, the piezoelectric layer 123 includes the piezoelectric portion 123a disposed in the central portion S and the curved portion 123b disposed in the extension portion E. The piezoelectric portion 123a is a portion directly stacked on the upper surface of the first electrode 121. Therefore, the piezoelectric portion 123a is interposed between the first electrode 121 and the second electrode 125 to be formed as a flat shape, together with the first electrode 121 and the second electrode 125. The curved portion 123b is a region extending outwardly from the piezoelectric portion 123a and positioned in the extension portion E.

The curved portion 123b is disposed on the insertion layer 170, which will be described in more detail later, and is formed in a shape in which the upper surface of the curved portion 123b is raised along the shape of the insertion layer 170. Accordingly, the piezoelectric layer 123 is curved at a boundary between the piezoelectric portion 123a and the curved portion 123b, and the curved portion 123b is raised corresponding to the thickness and the shape of the insertion layer 170.

The curved portion 123b may the inclined portion 1231 and an extension portion 1232. The inclined portion 1231 is a portion formed to be inclined along an inclined surface L of the insertion layer 170 to be described in more detail later. The extension portion 1232 is a portion extending externally from the inclined portion 1231.

The inclined portion 1231 may be formed parallel to the inclined surface L of the insertion layer 170, and an inclination angle of the inclined portion 1231 may be formed to be the same as an inclination angle of the inclined surface L of the insertion layer 170.

The insertion layer 170 is disposed along a surface formed by the membrane layer 150, the first electrode 121, and the etch stop portion 145. Therefore, the insertion layer 170 is partially disposed in the resonator portion 120, and is disposed between the first electrode 121 and the piezoelectric layer 123.

The insertion layer 170 is disposed at a periphery of the central portion S to support the curved portion 123b of the piezoelectric layer 123. Accordingly, the curved portion 123b of the piezoelectric layer 123 may include an inclined portion 1231 and an extension portion 1232 formed according to the shape of the insertion layer 170.

In the embodiment illustrated in FIGS. 1-4, the insertion layer 170 is disposed in a region excluding the central portion S. For example, the insertion layer 170 may be disposed on the substrate 110 in an entire region except for the central portion S, or in some regions.

The insertion layer 170 is formed to have a thickness that increases as a distance from the central portion S increases. Thereby, the insertion layer 170 includes the inclined surface L formed on a side surface disposed adjacent to the central portion S, and the inclined surface L may have a constant inclination angle θ.

It is difficult to manufacture the inclined surface L on the side surface of the insertion layer 170 to form the inclination angle θ to be smaller than 5° , since the thickness of the insertion layer 170 would be formed to be very thin or an area of the inclined surface L would be formed to be excessively large.

In addition, when the inclination angle θ of the side surface of the insertion layer 170 is formed to be greater than 70°, the inclination angle of the portion of the piezoelectric layer 123 or the portion of the second electrode 125 stacked on the insertion layer 170 is also formed to be greater than 70°. In this case, since the portion of the piezoelectric layer 123 or the portion of the second electrode 125 stacked on the inclined surface L is excessively curved, cracks may be generated in the curved portion 123b of the piezoelectric layer 123 or a corresponding curved portion of the second electrode 125.

Therefore, in the embodiment of FIGS. 1-4, the inclination angle θ of the inclined surface L is formed in a range of 5° to 70°.

The inclined portion 1231 of the piezoelectric layer 123 is formed along the inclined surface L of the insertion layer 170, and thus is formed at the same inclination angle as the inclined surface L of the insertion layer 170. Therefore, the inclination angle of the inclined portion 1231 is also formed in a range of 5° to 70°, similarly to the inclined surface L of the insertion layer 170. The configuration may also be equally applied to an inclined portion of the second electrode 125 stacked on the inclined surface L of the insertion layer 170.

The insertion layer 170 may be formed of a dielectric material such as silicon oxide (SiO₂), aluminum nitride(AlN), aluminum oxide (Al₂O₃), silicon nitride (Si₃N₄), magnesium oxide (MgO), zirconium oxide (ZrO₂), lead zirconate(PZT), gallium arsenide(GaAs), hafnium oxide(HfO₂), titanium oxide(TiO₂), zinc oxide (ZnO), or the like, but may be formed a material different from that of the piezoelectric layer 123.

In addition, the insertion layer 170 may be formed of a metal material. When the bulk-acoustic wave resonator 100 is used for 5G communications, since a lot of heat is generated from the resonator portion 120, the heat generated by the resonator portion 120 needs to be smoothly discharged. To this end, the insertion layer 170 may be made of an aluminum alloy material containing scandium (Sc).

In addition, the insertion layer 170 may be formed of an SiO₂ thin film injected with nitrogen (N) or fluorine (F).

The resonator portion 120 may be disposed to be spaced apart from the substrate 110 through the cavity C, which is formed as an empty space.

The cavity C may be formed by removing a portion of the sacrificial layer 140 by supplying etching gas (or an etching solution) to an inlet hole H (FIG. 1) during a manufacturing process of the acoustic wave resonator 100.

The protective layer 160 is disposed along the surface of the acoustic wave resonator 100 to protect the acoustic wave resonator 100 from the outside environment. The protective layer 160 may be disposed along a surface formed by the second electrode 125 and the piezoelectric portion 123b of the piezoelectric layer 123.

The first electrode 121 and the second electrode 125 may extend externally of the resonator portion 120. A first metal layer 180 and a second metal layer 190 may be disposed on an upper surface of the extended portions of the first electrode 121 and the second electrode 125, respectively.

The first metal layer 180 and the second metal layer 190 may be made of any one or any combination of any two or more of gold (Au), a gold-tin (Au—Sn) alloy, copper (Cu), a copper-tin (Cu—Sn) alloy, and aluminum (Al), and an aluminum alloy. The aluminum alloy may be an aluminum-germanium (Al—Ge) alloy or an aluminum-scandium (Al—Sc) alloy.

The first metal layer 180 and the second metal layer 190 may function as a connection wiring electrically connecting the first electrode 121 and the second electrode 125 of the bulk-acoustic wave resonator 100 to electrodes of other acoustic wave resonators disposed adjacent to the bulk-acoustic wave resonator 100 on the substrate 110.

The first metal layer 180 penetrates through the protective layer 160 and is bonded to the first electrode 121.

In addition, in the resonator portion 120, the first electrode 121 may be formed to have a larger area than an area of the second electrode 125, and the first metal layer 180 may be formed on a circumferential portion of the first electrode 121. Therefore, the first metal layer 180 may be disposed at the periphery of the resonator portion 120 and, accordingly, may be disposed to surround the second electrode 125. However, the disclosure is not limited to such a configuration.

In addition, the protective layer 160 is disposed such that at least a portion of the protective layer 160 is in contact with the first metal layer 180 and the second metal layer 190. The first metal layer 180 and the second metal layer 190 are formed of a metal material having high thermal conductivity, and have a large volume, so that a heat dissipation effect is high.

Thus, the protective 160 is connected to the first metal layer 180 and the second metal layer 190 so that heat generated from the piezoelectric layer 123 may be quickly transferred to the fist metal layer 180 and the second metal layer 190 via the protective layer 160.

In the embodiment of FIGS. 1-4, at least a portion of the protective layer 160 is disposed below the first and second metal layers 180 and 190. Specifically, the protective layer 160 is interposed between the first metal layer 180 and the piezoelectric layer 123, and between the second metal layer 190 and the second electrode 125, and the piezoelectric layer 123, respectively.

The bulk-acoustic wave resonator 100 may be doped with an element such as scandium (Sc) in aluminum nitride (AlN) in order to increase a bandwidth of the resonator portion 120 by increasing a piezoelectric constant of the piezoelectric layer 123.

As described above, when the piezoelectric layer 123 is formed by doping aluminum nitride (AlN) with scandium (Sc), a piezoelectric constant may be increased to increase the Kₜ² of the bulk-acoustic wave resonator 100.

In order for the bulk-acoustic wave resonator 100 to be used for 5G communication, the piezoelectric layer 123 must have a high piezoelectric constant capable of smoothly operating at a corresponding frequency. As a result of the measurement, it was found that, in order to be used for 5G communications, the piezoelectric layer 123 should contain 10 wt % or more of scandium (Sc) in aluminum nitride (AlN). Therefore, in this embodiment, the piezoelectric layer 123 may be formed of an AlScN material having a scandium (Sc) content of 10 wt % or more. Here, the scandium (Sc) content is defined based on a weight of aluminum and scandium. That is, in an example in which the scandium (Sc) content is 10 wt % and a total weight of aluminum and scandium is 100g, a weight of scandium is 10g.

The piezoelectric layer 123 may be formed through a sputtering process, and a sputtering target used in the sputtering process may be an aluminum-scandium (AlSc) target, which may be manufactured by a melting method including melting aluminum (Al) and scandium (Sc) and then hardening the melted aluminum (Al) and scandium (Sc).

However, when an aluminum-scandium (AlSc) target with a scandium (Sc) content of 40 wt % or more is manufactured, since an Al₂Sc phase as well as an Al₃Sc phase is formed, there is a problem that the target is easily damaged during a handling process of the target due to the fragile Al₂Sc phase. In addition, when a high power of 1 kW or more is applied to a sputtering target mounted on a sputtering device in a sputtering process, a crack may occur in the sputtering target.

Therefore, in the embodiment of FIGS. 1-4, the piezoelectric layer 123 may be formed of an AlScN material having a scandium (Sc) content of 10 wt % to 40 wt %.

An analysis of a content of an Sc element in an AlScN thin film can be confirmed by an energy dispersive X-ray spectroscopy, a scanning electron microscopy (SEM) and a transmission electron microscope (TEM) analysis, but is not limited thereto. For example, an X-ray photoelectron spectroscopy (XPS)analysis may also be used.

In an example in which the piezoelectric layer 123 was composed of aluminum nitride (AlN) containing scandium (Sc), it was measured that a leakage current generated in the piezoelectric layer 123 also increased as the content of scandium (Sc) increased.

Leakage current density represents a leakage current per unit area, and the leakage current generated in the piezoelectric layer 123 is a major factor. An occurrence of the leakage current in the piezoelectric layer 123 can be attributed to two causes: a Schottky emission with an electrode interface; and a Poole-Frenkel emission generated inside the piezoelectric layer.

In addition, the leakage current may increase even when an orientation from a hexagonal closed packed (HCP) crystal structure of the AlScN piezoelectric layer 123 to the (0002) crystal surface is poor. In the AlScN piezoelectric layer 123, since scandium (Sc) atoms, which are larger than aluminum (Al) atoms, may be substituted for aluminum (Al) sites, deformation may occur in an AlScN unit lattice. Thus, when defect sites such as voids, dislocations, or the like, in the piezoelectric layer 123 increase, the leakage current may increase.

When the scandium (Sc) content in the piezoelectric layer 123 increases, defect sites may increase in the piezoelectric layer 123, and such defect sites may act as a factor of abnormal growth of the piezoelectric layer 123.

Therefore, when the piezoelectric layer 123 is formed of an AlScN material the leakage current density and the content of scandium (Sc) in the piezoelectric layer 123 must be considered together.

In addition, as the frequency of a bulk-acoustic wave resonator for 5G communication increases, the thickness of the resonator portion must be reduced. Accordingly, in the bulk-acoustic wave resonator 100, the thickness of the piezoelectric layer 123 may be formed to be 5000 Å or less.

However, as the thickness of the piezoelectric layer 123 decreases, the amount of leakage current from the piezoelectric layer 123 tends to increase. When the leakage current is large, a breakdown voltage of the piezoelectric layer 123 may be lowered, so that the piezoelectric layer 123 may be easily damaged in a high voltage/high power environment.

Accordingly, the bulk-acoustic wave resonator 100 is configured to satisfy the following Equations 1 and 2 with respect to the leakage current and the scandium (Sc) content of the piezoelectric layer 123, so as to stably operate in a high voltage/high power environment.

Leakage current characteristic<20 Equation 1

Leakage current characteristic=leakage current density (μA/cm²)×scandium (Sc) content (wt %) Equation 2

In Equation 2, the leakage current density is the leakage current density of the piezoelectric layer 123, and the scandium (Sc) content is the content of scandium (Sc) contained in the piezoelectric layer 123. In addition, the above-described leakage current characteristic is a factor defining the performance of a bulk-acoustic wave resonator that can be used as a filter in 5G communication.

When the bulk-acoustic wave resonator 100 has a leakage current characteristic of less than 20, the leakage current density of the piezoelectric layer 123 has a magnitude similar to that of pure aluminum nitride (AlN). Accordingly, since a loss in the piezoelectric layer 123 is minimized, the bulk-acoustic wave resonator 100 may provide optimum performance as a filter for 5G communication.

On the other hand, when the leakage current characteristic is 20 or more, the leakage current increases excessively (e.g., 2 μA/cm² or more), so that the breakdown voltage of the piezoelectric layer becomes very low, or the scandium (Sc) content is excessive (e.g., 40 wt % or more), so that abnormal growth increases in the piezoelectric layer, and accordingly, the characteristics of the bulk-acoustic wave resonator are deteriorated, so it is difficult to secure the performance of the bulk-acoustic wave resonator as the above-described filter.

Accordingly, the bulk-acoustic wave resonator 100 is configured to satisfy Equation 1 above by minimizing the leakage current density in the piezoelectric layer 123 made of AlScN.

In order to minimize the leakage current in the piezoelectric layer 123, the bulk-acoustic wave resonator 100 may be formed by performing a heat treatment on the piezoelectric layer 123 during a manufacturing process.

The heat treatment of the piezoelectric layer 123 may be performed through a rapid thermal annealing (RTA) process. In this embodiment, the RTA process may be performed at a temperature of 400° C. or higher for 1 minute to 30 minutes.

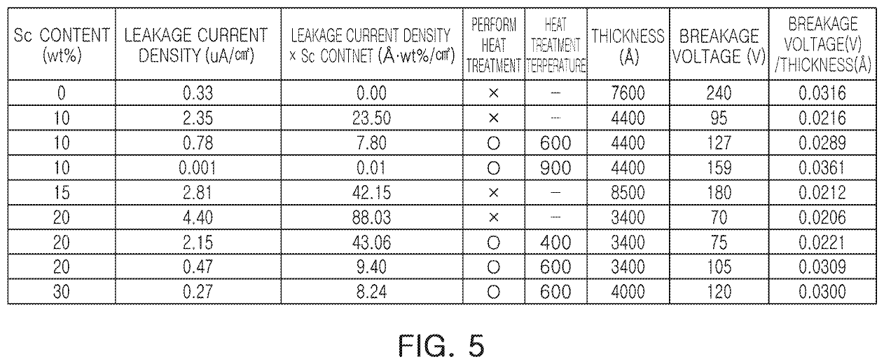

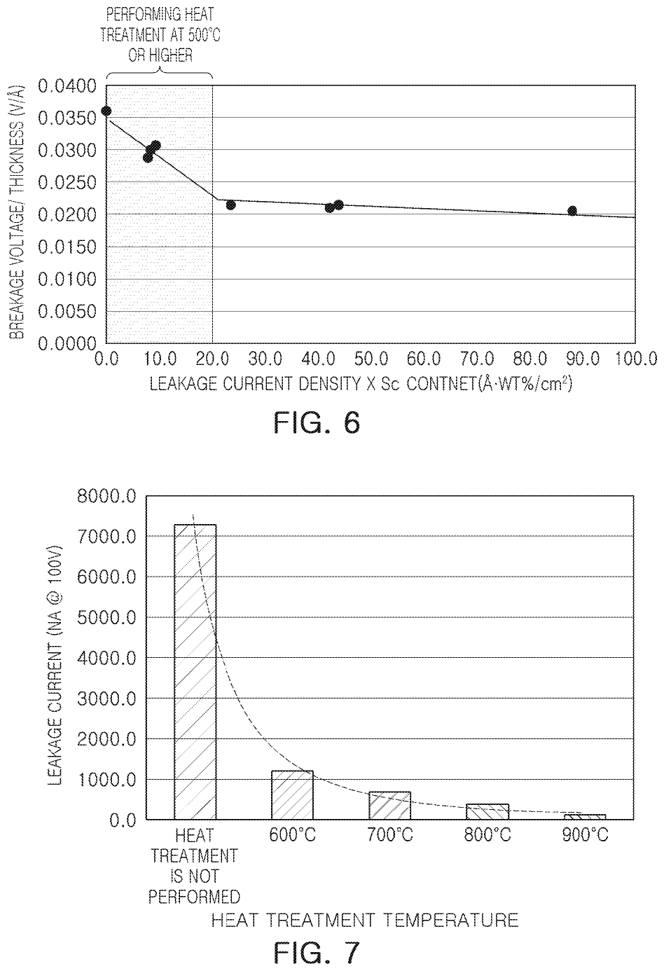

FIG. 5 is a diagram showing the measurement of leakage current density according to the scandium (Sc) content of a piezoelectric layer, and FIG. 6 is a graph created based on the leakage current characteristics of FIG. 5. Here, the leakage current density was measured while forming the same electric field of 0.1V/nm between the first electrode 121 and the second electrode 125.

Referring to FIG. 5, in an example in which a piezoelectric layer was formed of pure aluminum nitride (AlN) (i.e., the scandium (Sc) content was 0 wt %), the piezoelectric layer was measured to have leakage current density of 0.33 μA/cm². Still referring to FIG. 5, in examples in which a piezoelectric layer contained scandium (Sc), it was found that the leakage current density increased significantly. For example, the piezoelectric layer had leakage current densities of 2.35 μA/cm², 2.81 μA/cm², 4.40 μA/cm² at scandium (Sc) content levels of 10 wt %, 15 wt %, and 20 wt %, respectively.

On the other hand, in examples in which aluminum nitride (AlN) was doped with scandium (Sc) and then heat treatment was performed at 500° C. or higher to form a piezoelectric layer, leakage current density of the piezoelectric layer 123 was 0.78 μA/cm², 0.001 μA/cm², 0.47 μA/cm², and 0.27 μA/cm², for example. Therefore, when the heat treatment was performed, leakage current density of the piezoelectric layer was measured to be similar to the leakage current density of the piezoelectric layer measured in the example in which the piezoelectric layer was formed of pure aluminum nitride (AlN) not containing scandium (Sc).

On the other hand, when the heat treatment was performed at a temperature of 500° C. or lower after doping aluminum nitride (AlN) with scandium (Sc) in the piezoelectric layer 123, it was measured that the leakage current density was still increased even if the RTA process was performed.

In addition, as shown in FIG. 6, it was found that a piezoelectric layer was not subjected to a heat treatment, or a piezoelectric layer subjected to a heat treatment at a temperature of less than 500° C. had leakage current characteristics of 20 or more.

Accordingly, the bulk-acoustic wave resonator 100 may include the piezoelectric layer 123 formed by doping aluminum nitride (AlN) with scandium (Sc) and then performing a heat treatment on the aluminum nitride (AlN) doped with scandium (Sc) at a temperature of 500° C. or higher.

As described above, when the leakage current density in a piezoelectric layer is high, the piezoelectric layer may be easily damaged in a high voltage/high power environment. Therefore, in order for prevention thereof and to use the bulk-acoustic wave resonator 100 as a filter in 5G communication, the bulk-acoustic wave resonator 100 may include the piezoelectric layer 123 having a leakage current characteristic of less than 20.

When the material of the piezoelectric layer 123 was composed of aluminum nitride (AlN) containing scandium (Sc) and was subjected to a heat treatment at a temperature of 500° C. or higher, the leakage current characteristics were all measured to be less than 10. Therefore, based on the measured data of the heat treated material composed of aluminum nitride (AlN) containing scandium (Sc), the leakage current characteristic of the piezoelectric layer 123 in the bulk-acoustic wave resonator 100 may be less than 10.

In addition, referring to FIG. 5, in the case of the piezoelectric layer to which the heat treatment was not performed and the piezoelectric layer to which the heat treatment was performed at a temperature of 500° C. or lower, the leakage current density was measured to be 2 μA/cm ² or more. Therefore, it can be seen that the leakage current characteristic is 20 or less in a range that the leakage current density is 2 μA/cm² or less, and thus, the leakage current density of the piezoelectric layer 123 may be defined as 2 μA/cm² or less.

Still referring to FIG. 5, each piezoelectric layer made of AlScN that was subject to a heat treatment at a temperature of 500° C. or higher was measured to have leakage current density of 1 μA/cm² or less. Therefore, when only a piezoelectric layer that was subject to a heat treatment at a temperature of 500° C. or higher is considered, the leakage current density of the piezoelectric layer may also be specified to be 1 μA/cm² or less.

In addition, when the piezoelectric layer contains scandium (Sc), a breakdown voltage of the piezoelectric layer may be 100V or more.

As shown in FIG. 5, when the leakage current characteristic was 20 or less, the breakdown voltage of the piezoelectric layer was measured to be 100V or more. Thus, it can be understood that the piezoelectric layer 123 containing scandium (Sc) can be used as a filter when the breakdown voltage is 100V or more.

In addition, as shown in FIG. 6, when the leakage current characteristic was 20 or less, a ratio (V/Å) of the breakdown voltage of the piezoelectric layer to the thickness of the piezoelectric layer was measured to be 0.025 or more.

Accordingly, in the embodiment of FIGS. 1-4, the piezoelectric layer 123 may be formed such that the ratio (V/Å) of the breakdown voltage of the piezoelectric layer 123 to the thickness of the piezoelectric layer 123 is 0.025 or more.

In the piezoelectric layer, leakage current characteristics may vary according to the heat treatment temperature. FIG. 7 is a graph measuring a leakage current according to an RTA process temperature.

Referring to FIG. 7, an AlScN piezoelectric layer containing 10 wt % of scandium (Sc) was formed to a thickness of 4000 Å, and the leakage current was measured after performing a heat treatment at various temperatures. It can be observed in FIG. 7 that the leakage current was significantly reduced when the heat treatment was performed compared to the case in which the heat treatment process is not performed, and the leakage current was further reduced as the heat treatment temperature increased.

Therefore, even if the scandium (Sc) content increases, a piezoelectric layer satisfying Equation 1 can be manufactured by optimizing a heat treatment temperature.

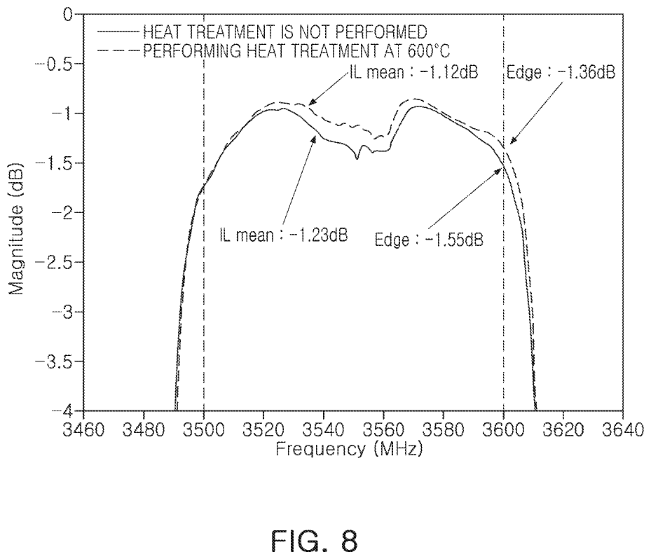

FIG. 8 is a graph illustrating the characteristics of a filter using the bulk-acoustic wave resonator 100, and showing an insertion loss according to a frequency band. In addition, FIG. 8 shows a graph of the bulk-acoustic wave resonator 100 satisfying Equation 1 through a heat treatment process and a bulk-acoustic wave resonator not satisfying Equation 1 (not subjected to a heat treatment process).

Referring to FIG. 8, a bulk-acoustic wave resonator 100 satisfying Equation 1 has improved mean insertion loss of −1.12 dB, as compared to a mean insertion loss of −1.23 dB of a bulk-acoustic wave resonator not satisfying Equation 1. Additionally, in the bulk acoustic wave resonator 100 satisfying Equation 1, the insertion loss at 3.6 GHz is improved from −1.55 dB to −1.36 dB.

Therefore, when the piezoelectric layer 123 is formed so that the leakage current characteristic satisfies Equation 1, it can be seen that the loss in the piezoelectric layer 123 is minimized, and thus the characteristics of the filter including the bulk-acoustic wave resonator 100 are improved.

In the bulk-acoustic wave resonator 100 configured as described above, as shown in FIG. 2, a resonator portion 120 may be formed by sequentially stacking a first electrode 121, a piezoelectric layer 123, and a second electrode 125 on the substrate 120. In addition, the operation of forming the resonator portion 120 may include an operation of disposing an insertion layer 170 below the first electrode 121 or between the first electrode 121 and the piezoelectric layer 123.

Therefore, the insertion layer 170 may be disposed to be stacked on the first electrode 121, or the first electrode 121 may be disposed to be stacked on the insertion layer 170.

The piezoelectric layer 123 and the second electrode 125 may be partially raised along the shape of the insertion layer 170, and the piezoelectric layer 123 may be formed on the first electrode 121 or the insertion layer 170.

In addition, the operation of preparing the piezoelectric layer 123 may include an operation of forming an AlScN thin film containing scandium (Sc) through a sputtering process with an aluminum-scandium (AlSc) target, and an operation of performing an RTA process on the AlScN thin film to complete the piezoelectric layer 123.

The bulk-acoustic wave resonator 100 may have the piezoelectric layer 123 having a leakage current characteristic of less than 20 since defects formed in the AlScN piezoelectric layer 123 may be removed through the RTA process. Accordingly, even though the piezoelectric layer 123 contains scandium (Sc), a leakage current is generated at a level of pure aluminum nitride (AlN), so that Kt² of the bulk-acoustic wave resonator 100 may be increased, and at the same time, stable characteristics can be maintained even under high voltage/high power conditions.

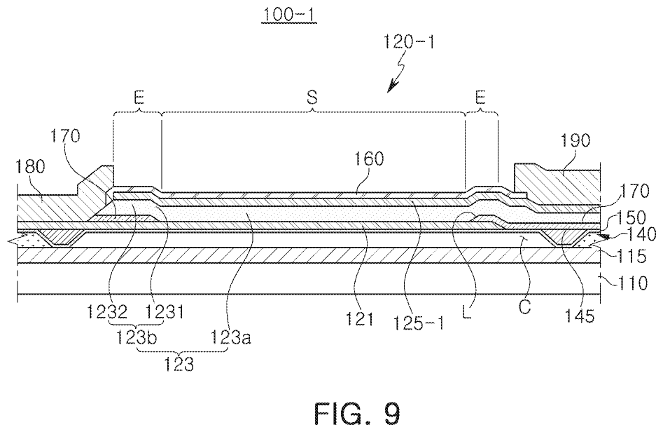

FIG. 9 is a schematic cross-sectional view of a bulk-acoustic wave resonator 100-1, according to an embodiment.

In the bulk-acoustic wave resonator 100, a second electrode 125-1 may be disposed on an entire upper surface of the piezoelectric layer 123 in a resonator portion 120-1, and accordingly, at least a portion of the second electrode 125-1 may be formed not only on the inclined portion 1231 of the layer 123 but also on the extension portion 1232.

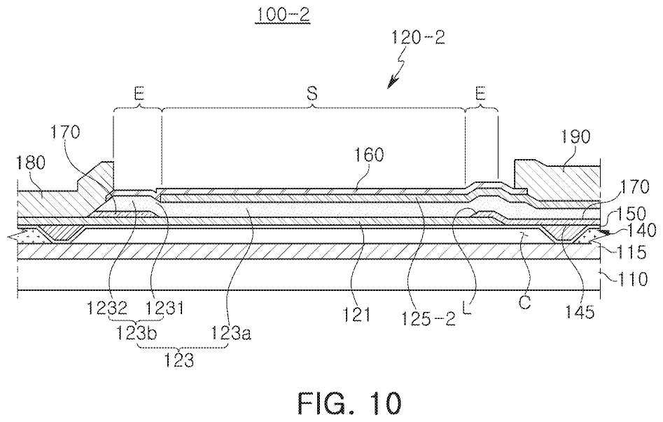

FIG. 10 is a schematic cross-sectional view of a bulk-acoustic wave resonator 100-2, according to an embodiment.

Referring to FIG. 10, in the bulk-acoustic wave resonator 100-2, in a cross-section of a resonator portion 120-2 cut to across the central portion S, an end portion of a second electrode 125-2 may be formed only on an upper surface of the piezoelectric portion 123a of the piezoelectric layer 123, and may not be formed on the bent portion 123b. Accordingly, the end of the second electrode 125-2 may be disposed along a boundary between the piezoelectric part 123a and the inclined portion 1231.

As described above, a bulk-acoustic wave resonator according to the disclosure herein can be modified in various forms, as necessary.

As set forth above, in a bulk-acoustic wave resonator described herein, Kt² may be increased, and at the same time, stable characteristics may be maintained even under high voltage/high power conditions.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk-acoustic wave resonator, comprising:
a substrate; and
a resonator portion in which a first electrode, a piezoelectric layer, and a second electrode are sequentially stacked on the substrate,
wherein the piezoelectric layer is formed of aluminum nitride (AlN) containing scandium (Sc),
wherein the bulk-acoustic wave resonator satisfies the following expression:
leakage current density x scandium (Sc) content<20, and
wherein the leakage current density is a leakage current density of the piezoelectric layer in μA/cm², and the scandium (Sc) content is a weight percentage (wt %) of scandium (Sc) in the piezoelectric layer.

2. The bulk-acoustic wave resonator of claim 1, wherein the scandium content is 10 wt % to 40 wt %.

3. The bulk-acoustic wave resonator of claim 1, wherein the leakage current density is 2 μA/cm²or less.

4. The bulk-acoustic wave resonator of claim 1, wherein a ratio of a breakdown voltage of the piezoelectric layer, in volts, to a thickness of the piezoelectric layer, in Å, is 0.025 or more.

5. The bulk-acoustic wave resonator of claim 1, further comprising an insertion layer partially disposed in the resonator portion and disposed below the piezoelectric layer,
wherein the piezoelectric layer and the second electrode are at least partially raised by the insertion layer.

6. The bulk-acoustic wave resonator of claim 5, wherein the resonator portion comprises a central portion disposed in a central region of the resonator portion and an extension portion disposed at a periphery of the central portion,
wherein the insertion layer is disposed only in the extension portion of the resonator portion,
wherein the insertion layer has an inclined surface having a thickness increasing in a direction away from the central portion, and
wherein the piezoelectric layer comprises an inclined portion disposed on the inclined surface.

7. The bulk-acoustic wave resonator of claim 6, wherein, in a cross-section cut to across the resonator portion, an end of the second electrode is disposed at a boundary between the central portion and the extension portion, or disposed on the inclined portion.

8. The bulk-acoustic wave resonator of claim 6, wherein the piezoelectric layer further comprises a piezoelectric portion disposed in the central portion and an extension portion extending outwardly of the inclined portion, and
wherein at least a portion of the second electrode is disposed on the extension portion of the piezoelectric layer.

9. A method for manufacturing a bulk-acoustic wave resonator, comprising:
forming a resonator portion in which a first electrode, a piezoelectric layer, and a second electrode are sequentially stacked on a substrate,
wherein the forming of the resonator portion comprises forming the piezoelectric layer by forming an aluminum scandium nitride (AlScN) thin film, and then performing a rapid thermal annealing (RTA) process on the AlScN thin film,
wherein the bulk-acoustic wave resonator satisfies the following expression:
leakage current density×scandium (Sc) content<20, and
wherein the leakage current density is a leakage current density of the piezoelectric layer in μA/cm², and the scandium (Sc) content is a weight percentage (wt %) of scandium (Sc) in the piezoelectric layer.

10. The method of claim 9, wherein the scandium (Sc) content is 10 wt % to 40 wt %.

11. The method of claim 9, wherein the forming of the AlScN thin film is performed through a sputtering process using aluminum-scandium (AlSc) as a target.

12. The method of claim 9, wherein the leakage current density is 2 μA/cm² or less.

13. The method of claim 9, wherein a ratio of a breakdown voltage of the piezoelectric layer, in volts, to a thickness of the piezoelectric layer, in Å, is 0.025 or more.

14. The method of claim 9, further comprising forming an insertion layer below the piezoelectric layer,
wherein the piezoelectric layer and the second electrode are at least partially raised by the insertion layer.

15. The method of claim 14, wherein the insertion layer has an inclined surface, and
wherein, in a cross-section cut to across the resonator portion, at least a portion of an end of the second electrode is disposed to overlap the insertion layer.

16. The method of claim 15, wherein the resonator portion comprises a central portion disposed in a central region of the resonator portion, and an extension portion disposed along a periphery of the central portion, and
wherein the end of the second electrode is disposed in the extension portion.

17. A bulk-acoustic wave resonator, comprising:
a substrate; and
a resonator portion in which a first electrode, a piezoelectric layer, and a second electrode are sequentially stacked on the substrate,
wherein the piezoelectric layer is formed of aluminum nitride (AlN) containing scandium (Sc) in an amount of 10 wt % to 40 wt %, and
wherein a leakage current density of the piezoelectric layer is 2 μA/cm² or less, as measured in an electric field of 0.1V/nm between the first electrode and the second electrode.

18. The bulk-acoustic wave resonator of claim 17, wherein a ratio of a breakdown voltage of the piezoelectric layer, in volts, to a thickness of the piezoelectric layer, in Å, is 0.025 or more.

19. The bulk-acoustic wave resonator of claim 17, wherein the piezoelectric layer contains scandium in an amount of 10 wt % to 30 wt %.

20. The bulk-acoustic wave resonator of claim 17, further comprising an insertion layer disposed below the piezoelectric layer in the resonator portion,
wherein portions of the piezoelectric layer and the second electrode are inclined by the insertion layer.

21. A method for manufacturing a bulk-acoustic wave resonator, comprising:
forming a resonator portion in which a first electrode, a piezoelectric layer, and a second electrode are sequentially stacked on a substrate,
wherein the forming of the resonator portion comprises forming the piezoelectric layer by forming an aluminum scandium nitride (AlScN) thin film containing scandium (Sc) in an amount of 10 wt % to 40 wt %, and then performing a rapid thermal annealing (RTA) process on the AlScN thin film at a temperature of 500° C. or higher.

22. The method of claim 21, wherein the AlScN thin film contains scandium in an amount of 10 wt % to 30 wt %.

23. The method of claim 21, wherein the performing of the rapid thermal annealing (RTA) process on the AlScN thin film at a temperature of 500° C. or higher comprises performing the rapid thermal annealing (RTA) process on the AlScN thin film at a temperature of 600° C. to 900° C.

24. The method of claim 21, wherein a leakage current density of the piezoelectric layer is 2 μA/cm² or less, as measured in an electric field of 0.1V/nm between the first electrode and the second electrode.
